(19) United States
(12) Patent Application Publication
(10) Pub. No.: US 2026/0040658 A1
(43) Pub. Date: Feb. 5, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 19/070,443

(22) Filed: Mar. 4, 2025

(30) Foreign Application Priority Data
Aug. 1, 2024 (JP) 2024-126179

(51) Int. Cl. H10D 84/00; H10D 8/00; H10D 8/60; H10D 30/66; H10D 62/10; H10D 62/60; H10D 62/832

(52) U.S. Cl. CPC H10D 84/146; H10D 8/411; H10D 8/60; H10D 30/665; H10D 62/102; H10D 62/124; H10D 62/60; H10D 62/8325; H10D 84/143

(57) ABSTRACT

A semiconductor device of embodiments includes an element region, a termination region, and an intermediate region between the element region and the termination region. The element region includes: a silicon carbide layer having a first conductive type silicon carbide region and a second conductive type of silicon carbide regions; and a gate electrode. The intermediate region includes a silicon carbide layer having a second conductive type silicon carbide region outside the second conductive type silicon carbide regions. The width of the second conductive type silicon carbide region in the intermediate region is equal to or more than 0.5 times and equal to or less than 3 times the width of the second conductive type silicon carbide region in the element region.

### CROSS-REFERENCE TO RELATED APPLICATION

This application is based upon and claims the benefit of priority from Japanese Patent Application No. 2024-126179, filed on Aug. 1, 2024, the entire contents of which are incorporated herein by reference.

### FIELD

Embodiments described herein relate generally to a semiconductor device.

### BACKGROUND

Silicon carbide is expected as a material for semiconductor devices. Silicon carbide has excellent physical properties, such as a bandgap of 3 times that of silicon, a breakdown field strength of about 10 times that of silicon, and a thermal conductivity of about 3 times that of silicon. By using such characteristics, for example, it is possible to realize a metal oxide semiconductor field effect transistor (MOSFET) that has a high breakdown voltage and low loss and that can operate at high temperature.

A vertical MOSFET using silicon carbide has a pn junction diode as a built-in diode. For example, a MOSFET is used as a switching element connected to an inductive load. In this case, even when the MOSFET is in an off state, a reflux current can be made to flow by using a pn junction diode.

However, when a reflux current is made to flow by using a pn junction diode that operates in a bipolar manner, a stacking fault grows in a silicon carbide layer due to the recombination energy of the carriers. If the stacking fault grows in the silicon carbide layer, there arises a problem that the on-resistance of the MOSFET increases. The increase in the on-resistance of the MOSFET reduces the reliability of the MOSFET. For example, by providing a Schottky barrier diode (SBD) operating in a unipolar manner in the MOSFET as a built-in diode, it is possible to suppress the growth of a stacking fault in the silicon carbide layer.

### BRIEF DESCRIPTION OF THE DRAWINGS

FIGS. 1A and 1B are schematic top views of a semiconductor device according to a first embodiment;

FIGS. 2A and 2B are schematic top views of the semiconductor device according to the first embodiment;

FIG. 3 is a schematic cross-sectional view of the

semiconductor device according to the first embodiment;

FIG. 4 is an equivalent circuit diagram of the semiconductor device according to the first embodiment;

FIG. 5 is a schematic cross-sectional view of a semiconductor device according to a comparative example;

FIG. 6 is an explanatory diagram of the function and effect of the semiconductor device according to the first embodiment;

FIG. 7 is an explanatory diagram of the function and effect of the semiconductor device according to the first embodiment; and

FIG. 8 is a schematic cross-sectional view of a semiconductor device according to a second embodiment.

### DETAILED DESCRIPTION

A semiconductor device of embodiments includes an element region, a termination region surrounding the element region, and an intermediate region provided between the element region and the termination region and surrounding the element region. The element region includes: a first electrode; a second electrode; a gate electrode; a silicon carbide layer provided between the first electrode and the second electrode, having a first face on the first electrode side and a second face on the second electrode side, and including a first silicon carbide region of a first conductive type having a first region, a second region provided between the first region and the first face and having a higher first conductive type impurity concentration than the first region, a first portion in contact with the first face and facing the gate electrode, and a second portion in contact with the first face and in contact with the first electrode, a second silicon carbide region of a second conductive type provided between the second region and the first face and electrically connected to the first electrode, a third silicon carbide region of the second conductive type provided between the second region and the first face, provided on the intermediate region side of the second silicon carbide region, and electrically connected to the first electrode, a fourth silicon carbide region of the second conductive type provided between the second region and the first face, provided between the second silicon carbide region and the third silicon carbide region, facing the gate electrode, and electrically connected to the first electrode, a fifth silicon carbide region of the second conductive type provided between the second region and the first face, provided between the second silicon carbide region and the fourth silicon carbide region, facing the gate electrode, and electrically connected to the first electrode, a sixth silicon carbide region of the second conductive type provided between the second region and the first face, provided between the third silicon carbide region and the fourth silicon carbide region, and having a depth smaller than a depth of the third silicon carbide region and a depth of the fourth silicon carbide region, and a seventh silicon carbide region of the first conductive type provided between the fifth silicon carbide region and the first face and electrically connected to the first electrode; and a gate insulating layer provided between the gate electrode and the fifth silicon carbide region and between the gate electrode and the first portion. The termination region includes: a wiring layer electrically connected to the first electrode; the second electrode; and the silicon carbide layer including the first silicon carbide region having a third portion in contact with the first face and in contact with the wiring layer and an eighth silicon carbide region of the second conductive type provided between the first silicon carbide region and the first face, electrically connected to the wiring layer, and having a smaller depth than the third silicon carbide region. The intermediate region includes: the second electrode; and the silicon carbide layer including the first silicon carbide region, a ninth silicon carbide region of the second conductive type provided between the first silicon carbide region and the first face, electrically connected to the first electrode, in contact with the third silicon carbide region and the eighth silicon carbide region, and having a smaller depth than the third silicon carbide region, and a tenth silicon carbide region of the second conductive type provided between the first silicon carbide region and the ninth silicon carbide region. A first width of the tenth silicon carbide region in a first direction parallel to the first face is equal to or more than 0.5 times and equal to or less than 3 times a second width of the fourth silicon carbide region in the first direction, and a first distance in the first direction between the tenth silicon carbide region and the third silicon carbide region is equal to or more than 0.5 times and equal to or less than 3 times a second distance in the first direction between the fourth silicon carbide region and the fifth silicon carbide region.

Hereinafter, embodiments will be described with reference to the diagrams. In the following description, the same or similar members and the like may be denoted by the same reference numerals, and the description of the members and the like once described may be omitted as appropriate.

In addition, in the following description, when there are notations of n⁺, n, n⁻, p⁺, p, and p⁻, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

In addition, unless otherwise specified in this specification, the “impurity concentration” means a concentration when the impurity concentration of the opposite conductive type is compensated for. That is, the n-type impurity concentration in an n-type silicon carbide region means a concentration obtained by subtracting the concentration of p-type impurities from the concentration of n-type impurities. In addition, the p-type impurity concentration in a p-type silicon carbide region means a concentration obtained by subtracting the concentration of n-type impurities from the concentration of p-type impurities. In addition, unless otherwise specified in this specification, the “impurity concentration in the silicon carbide region” is a maximum impurity concentration in the corresponding silicon carbide region.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, distances such as the depth and thickness of the impurity region can be calculated by using, for example, an SIMS or a Scanning Electron Microscope (SEM). In addition, the depth, thickness, and width of an impurity region and a distance such as a gap between impurity regions can be calculated from, for example, a composite image of an SCM image and an atomic force microscope (AFM) image.

### First Embodiment

A semiconductor device according to a first embodiment includes an element region, a termination region surrounding the element region, and an intermediate region provided between the element region and the termination region and surrounding the element region. The element region includes: a first electrode; a second electrode; a gate electrode; a silicon carbide layer provided between the first electrode and the second electrode, having a first face on the first electrode side and a second face on the second electrode side, and including a first silicon carbide region of a first conductive type having a first region, a second region provided between the first region and the first face and having a higher first conductive type impurity concentration than the first region, a first portion in contact with the first face and facing the gate electrode, and a second portion in contact with the first face and in contact with the first electrode, a second silicon carbide region of a second conductive type provided between the second region and the first face and electrically connected to the first electrode, a third silicon carbide region of the second conductive type provided between the second region and the first face, provided on the intermediate region side of the second silicon carbide region, and electrically connected to the first electrode, a fourth silicon carbide region of the second conductive type provided between the second region and the first face, provided between the second silicon carbide region and the third silicon carbide region, facing the gate electrode, and electrically connected to the first electrode, a fifth silicon carbide region of the second conductive type provided between the second region and the first face, provided between the second silicon carbide region and the fourth silicon carbide region, facing the gate electrode, and electrically connected to the first electrode, a sixth silicon carbide region of the second conductive type provided between the second region and the first face, provided between the third silicon carbide region and the fourth silicon carbide region, and having a depth smaller than a depth of the third silicon carbide region and a depth of the fourth silicon carbide region, and a seventh silicon carbide region of the first conductive type provided between the fifth silicon carbide region and the first face and electrically connected to the first electrode; and a gate insulating layer provided between the gate electrode and the fifth silicon carbide region and between the gate electrode and the first portion. The termination region includes: a wiring layer electrically connected to the first electrode; the second electrode; and the silicon carbide layer including the first silicon carbide region having a third portion in contact with the first face and in contact with the wiring layer and an eighth silicon carbide region of the second conductive type provided between the first silicon carbide region and the first face, electrically connected to the wiring layer, and having a smaller depth than the third silicon carbide region. The intermediate region includes: the second electrode; and the silicon carbide layer including the first silicon carbide region, a ninth silicon carbide region of the second conductive type provided between the first silicon carbide region and the first face, electrically connected to the first electrode, in contact with the third silicon carbide region and the eighth silicon carbide region, and having a smaller depth than the third silicon carbide region, and a tenth silicon carbide region of the second conductive type provided between the first silicon carbide region and the ninth silicon carbide region. A first width of the tenth silicon carbide region in a first direction parallel to the first face is equal to or more than 0.5 times and equal to or less than 3 times a second width of the fourth silicon carbide region in the first direction, and a first distance in the first direction between the tenth silicon carbide region and the third silicon carbide region is equal to or more than 0.5 times and equal to or less than 3 times a second distance in the first direction between the fourth silicon carbide region and the fifth silicon carbide region.

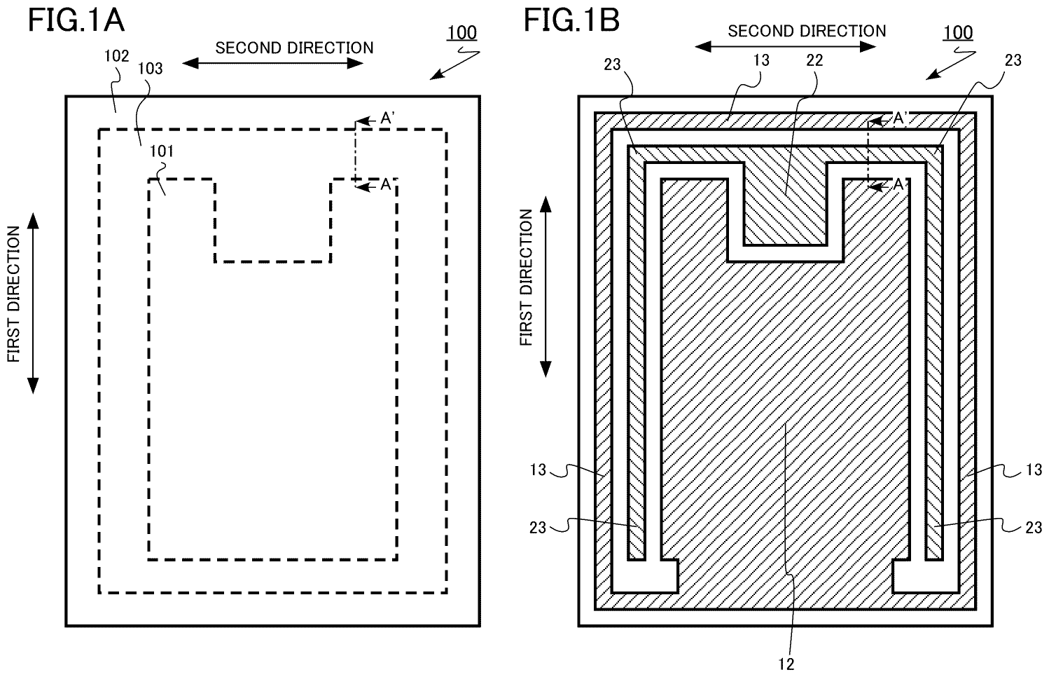

FIGS. 1A and 1B are schematic top views of the semiconductor device according to the first embodiment. FIG. 1A shows a layout pattern of an element region, a termination region, and an intermediate region. FIG. 1B shows a layout pattern of a source electrode, a source electrode wiring layer, a gate pad electrode, and a gate electrode wiring layer.

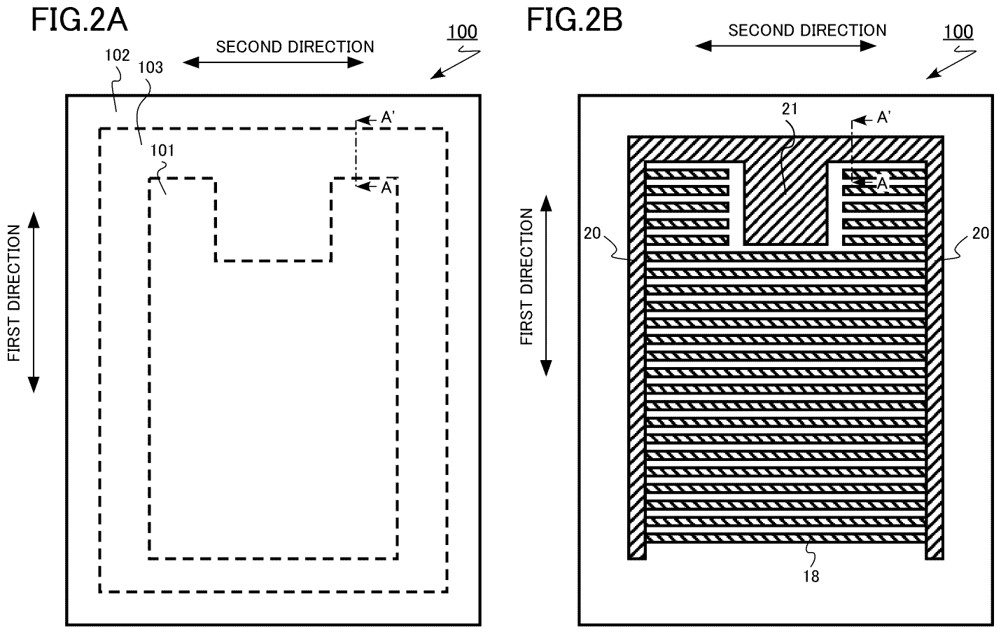

FIGS. 2A and 2B are schematic top views of the semiconductor device according to the first embodiment. FIG. 2A shows a layout pattern of an element region, a termination region, and an intermediate region. FIG. 2B shows a layout pattern of a gate electrode, a gate connection layer, and a gate pad layer.

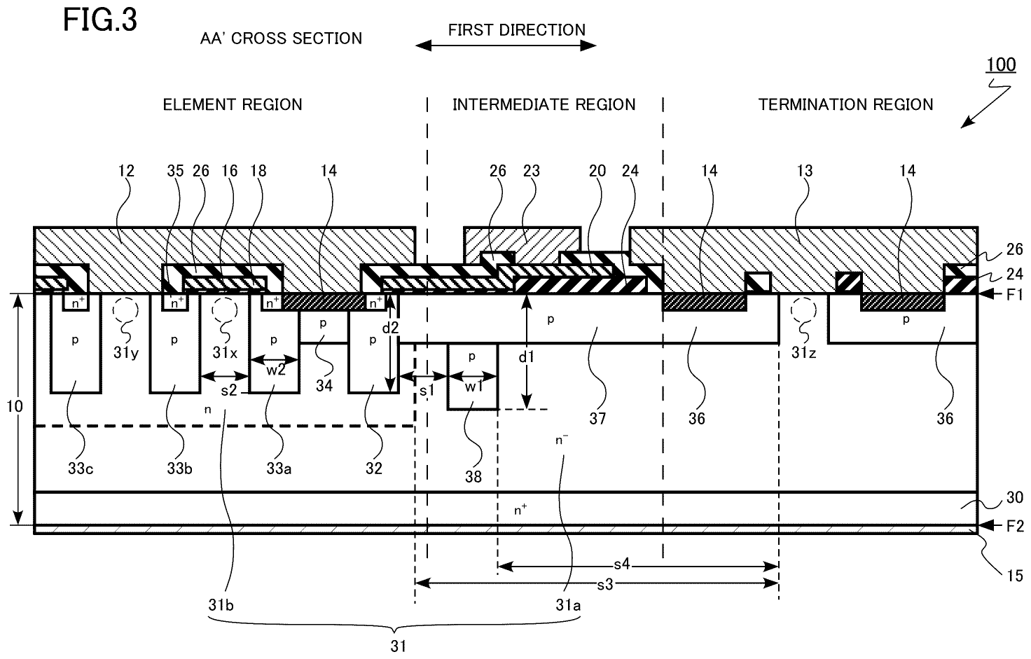

FIG. 3 is a schematic cross-sectional view of the semiconductor device according to the first embodiment. FIG. 3 is a cross-sectional view taken along the line AA′ shown in FIGS. 1A to 2B.

The semiconductor device according to the first embodiment is a planar gate type vertical MOSFET 100 using silicon carbide. The MOSFET 100 is, for example, a double implantation MOSFET (DIMOSFET) in which a base region and a source region are formed by ion implantation. In addition, the semiconductor device according to the first embodiment includes an SBD as a built-in diode.

Hereinafter, a case where the first conductive type is n-type and the second conductive type is p-type will be described as an example. The MOSFET 100 is a vertical n-channel MOSFET having electrons as carriers.

The MOSFET 100 includes a silicon carbide layer 10, a source electrode 12 (first electrode), a source electrode wiring layer 13 (wiring layer), a silicide layer 14, a drain electrode 15 (second electrode), a gate insulating layer 16, a gate electrode 18, a gate connection layer 20, a gate pad layer 21, a gate electrode pad 22, a gate electrode wiring layer 23, a field insulating layer 24, and an interlayer insulating layer 26.

The silicon carbide layer 10 includes an n+-type drain region 30, an n-type drift region 31 (first silicon carbide region), a p-type outer peripheral p region 32 (third silicon carbide region), a first base region 33a of p-type (fourth silicon carbide region), a second base region 33b of p-type (fifth silicon carbide region), a third base region 33c of p-type (second silicon carbide region), a first p region 34 of p-type (sixth silicon carbide region), an n⁺-type source region 35 (seventh silicon carbide region), a second p region 36 of p-type (eighth silicon carbide region), a third p region 37 of p-type (ninth silicon carbide region), and a fourth p region 38 of p-type (tenth silicon carbide region). The n-type drift region 31 (first silicon carbide region) has an n⁻-type low concentration region 31a (first region) and an n-type high concentration region 31b (second region). The n-type drift region 31 has a first portion 31x, a second portion 31y, and a third portion 31z.

Hereinafter, the first base region 33a (fourth silicon carbide region), the second base region 33b (fifth silicon carbide region), and the third base region 33c (second silicon carbide region) may be individually or collectively referred to as simply a base region 33.

The MOSFET 100 includes an element region 101, a termination region 102, and an intermediate region 103.

The termination region 102 surrounds the element region 101. The intermediate region 103 is provided between the element region 101 and the termination region 102. The termination region 102 surrounds the intermediate region 103. The intermediate region 103 surrounds the element region 101.

The element region 101 includes a plurality of MOSFETs and a plurality of SBDs. The termination region 102 includes an SBD.

The termination region 102 and the intermediate region 103 reduce the strength of the electric field applied to the termination portion of the pn junction of the element region 101 when the MOSFET 100 is in an off state. The termination region 102 and the intermediate region 103 have a function of increasing the dielectric breakdown voltage of the MOSFET 100.

The element region 101 includes the silicon carbide layer 10, the source electrode 12, the silicide layer 14, the drain electrode 15, the gate insulating layer 16, the gate electrode 18, the field insulating layer 24, and the interlayer insulating layer 26.

The silicon carbide layer 10 in the element region 101 includes the n⁺-type drain region 30, the n-type drift region 31 (first silicon carbide region), the p-type outer peripheral p region 32 (third silicon carbide region), the first base region 33a of p-type (fourth silicon carbide region), the second base region 33b of p-type (fifth silicon carbide region), the third base region 33c of p-type (second silicon carbide region), the first p region 34 of p-type (sixth silicon carbide region), and the n⁺-type source region 35 (seventh silicon carbide region). The drift region 31 of the element region 101 has the n⁻-type low concentration region 31a (first region) and the n-type high concentration region 31b (second region). The drift region 31 of the element region 101 has the first portion 31x and the second portion 31y.

The termination region 102 includes the silicon carbide layer 10, the source electrode wiring layer 13, the silicide layer 14, the drain electrode 15, and the interlayer insulating layer 26.

The silicon carbide layer 10 of the termination region 102 includes the n⁺-type drain region 30, the n-type drift region 31 (first silicon carbide region), and the second p region 36 of p-type (eighth silicon carbide region). The drift region 31 of the termination region 102 has the third portion 31z.

The intermediate region 103 includes the silicon carbide layer 10, the silicide layer 14, the drain electrode 15, the gate insulating layer 16, the gate connection layer 20, the gate pad layer 21, the gate electrode pad 22, the gate electrode wiring layer 23, the field insulating layer 24, and the interlayer insulating layer 26.

The silicon carbide layer 10 in the intermediate region 103 includes the n⁺-type drain region 30, the n-type drift region 31, the third p region 37 of p-type, and the fourth p region 38 of p-type.

The silicon carbide layer 10 is provided between the source electrode 12 and the drain electrode 15. The silicon carbide layer 10 is a single crystal SiC. The silicon carbide layer 10 is, for example, 4H-SiC.

The silicon carbide layer 10 has a first face (“F1” in FIG. 3) and a second face (“F2” in FIG. 3). Hereinafter, the first face F1 may be referred to as a surface, and the second face F2 may be referred to as a back surface. The first face F1 is disposed on the source electrode 12 side of the silicon carbide layer 10. In addition, the second face F2 is disposed on the drain electrode 15 side of the silicon carbide layer 10. The first face F1 and the second face F2 face each other. Hereinafter, the “depth” means a depth in a direction toward the second face with the first face as a reference.

The first face is parallel to the first and second directions. The second direction is perpendicular to the first direction.

The first face F1 is, for example, a face inclined by an angle equal to or more than 0° and equal to or less than 8° with respect to the (0001) face. In addition, the second face F2 is, for example, a face inclined by an angle equal to or more than 0° and equal to or less than 8° with respect to the (000-1) face. The (0001) face is referred to as a silicon face. The (000-1) face is referred to as a carbon face.

The thickness of the silicon carbide layer 10 is, for example, equal to or more than 5 μm and equal to or less than 350 μm.

The n⁺-type drain region 30 is provided on the back surface side of the silicon carbide layer 10. The drain region 30 contains, for example, nitrogen (N) as an n-type impurity. The n-type impurity concentration in the drain region 30 is equal to or more than 1×10¹⁸ cm⁻³ and equal to or less than 1×10²¹ cm⁻³, for example.

The n-type drift region 31 is provided between the drain region 30 and the first face F1. The n-type drift region 31 is provided between the source electrode 12 and the drain electrode 15. The n-type drift region 31 is provided between the gate electrode 18 and the drain electrode 15. The n-type drift region 31 is provided on the drain region 30.

The drift region 31 contains, for example, nitrogen (N) as an n-type impurity. The n-type impurity concentration in the drift region 31 is lower than the n-type impurity concentration in the drain region 30. The n-type impurity concentration in the drift region 31 is equal to or more than 4×10¹⁴ cm⁻³ and equal to or less than 5×10¹⁷ cm⁻³, for example. The thickness of the drift region 31 is, for example, equal to or more than 3 μm and equal to or less than 100 μm.

The drift region 31 has the n⁻-type low concentration region 31a and the n-type high concentration region 31b in the element region 101. The high concentration region 31b is provided between the low concentration region 31a and the first face F1.

The drift region 31 includes the first portion 31x and the second portion 31y in the element region 101. The first portion 31x and the second portion 31y are included in the high concentration region 31b.

The first portion 31x is in contact with the first face F1, and faces the gate electrode 18 with the gate insulating layer 16 interposed therebetween. The first portion 31x functions as, for example, a current path for the MOSFET in the element region 101.

The second portion 31y is in contact with the first face F1, and is in contact with the source electrode 12. The second portion 31y functions as, for example, a current path for the SBD in the element region 101. In the second direction of the second portion 31y, for example, the silicide layer 14 is provided.

The p-type base region 33 is provided between the drift region 31 and the first face F1. The base region 33 is provided between the high concentration region 31b and the first face F1.

The base region 33 extends, for example, in the second direction. For example, a plurality of base regions 33 are repeatedly arranged in the first direction.

The base region 33 includes, for example, the first base region 33a, the second base region 33b, and the third base region 33c of p-type. The first base region 33a is provided between the third base region 33c and the outer peripheral p region 32. The second base region 33b is provided between the third base region 33c and the first base region 33a.

The base region 33 functions as a channel region of the MOSFET 100.

The width of the base region 33 in the first direction is, for example, equal to or more than 0.5 μm and equal to or less than 2.0 μm. The second width (w2 in FIG. 3) of the first base region 33a in the first direction is, for example, equal to or more than 0.5 μm and equal to or less than 2.0 μm.

The distance in the first direction between the two base regions 33 adjacent to each other in the first direction is, for example, equal to or more than 0.5 μm and equal to or less than 2.0 μm. A second distance (s2 in FIG. 3) in the first direction between the first base region 33a and the second base region 33b is, for example, equal to or more than 0.5 μm and equal to or less than 2.0 μm.

The depth of the base region 33 is, for example, equal to or more than 1.0 μm and equal to or less than 2.0 μm.

The base region 33 is electrically connected to the source electrode 12. The base region 33 is fixed to the electric potential of the source electrode 12.

A part of the base region 33 is in contact with the first face F1. A part of the base region 33 faces the gate electrode 18. For example, a part of the first base region 33a faces the gate electrode 18. For example, a part of the second base region 33b faces the gate electrode 18.

The gate insulating layer 16 is interposed between a part of the base region 33 and the gate electrode 18.

The base region 33 contains, for example, aluminum (Al) as a p-type impurity. The p-type impurity concentration in the base region 33 is, for example, equal to or more than 5×10¹⁷ cm⁻³ and equal to or less than 1×10²⁰ cm⁻³.

The p-type outer peripheral p region 32 is provided between the drift region 31 and the first face F1. The outer peripheral p region 32 is provided between the high concentration region 31b and the first face F1.

The outer peripheral p region 32 is provided on the outer periphery of the base region 33. The outer peripheral p region 32 is provided on the intermediate region 103 side of the base region 33. The outer peripheral p region 32 is provided on the intermediate region 103 side of the third base region 33c. For example, the outer peripheral p region 32 surrounds the base region 33 on the first face F1.

The width of the outer peripheral p region 32 in the first direction is, for example, equal to or more than 0.5 μm and equal to or less than 2.0 μm. The width of the outer peripheral p region 32 in the first direction is substantially the same as the width of the base region 33 in the first direction, for example.

The distance in the first direction between the outer peripheral p region 32 and the first base region 33a is, for example, equal to or more than 0.5 μm and equal to or less than 2.0 μm. For example, the distance in the first direction between the outer peripheral p region 32 and the first base region 33a is substantially equal to the distance in the first direction between the two base regions 33 adjacent to each other in the first direction.

A second depth (d2 in FIG. 3) of the outer peripheral p region 32 is, for example, equal to or more than 1.0 μm and equal to or less than 2.0 μm. The second depth d2 of the outer peripheral p region 32 is substantially the same as the depth of the base region 33, for example.

The outer peripheral p region 32 is electrically connected to the source electrode 12. The outer peripheral p region 32 is fixed at the electric potential of the source electrode 12.

The outer peripheral p region 32 contains, for example, aluminum (Al) as a p-type impurity. The p-type impurity concentration in the outer peripheral p region 32 is, for example, equal to or more than 5×10¹⁷ cm⁻³ and equal to or less than 1×10²⁰ cm⁻³. The p-type impurity concentration in the outer peripheral p region 32 is substantially the same as the p-type impurity concentration in the base region 33, for example.

The outer peripheral p region 32 is formed by the same manufacturing process using the same mask pattern as for the base region 33, for example.

The first p region 34 of p-type is provided between the drift region 31 and the first face F1. The first p region 34 is provided between the high concentration region 31b and the first face F1.

The first p region 34 is provided, for example, between the two base regions 33 adjacent to each other in the first direction. The first p region 34 is provided between the outer peripheral p region 32 and the first base region 33a. The first p region 34 is provided between the silicide layer 14 and the high concentration region 31b.

The depth of the first p region 34 is smaller than the second depth d2 of the outer peripheral p region 32 and the depth of the base region 33. The depth of the first p region 34 is smaller than the depth of the first base region 33a, for example. The depth of the first p region 34 is, for example, equal to or more than 0.5 μm and equal to or less than 1 μm.

The first p region 34 is electrically connected to the source electrode 12. The first p region 34 is fixed to the electric potential of the source electrode 12.

The first p region 34 contains, for example, aluminum (Al) as a p-type impurity. The p-type impurity concentration in the first p region 34 is, for example, equal to or more than 5×10¹⁷ cm⁻³ and equal to or less than 1×10²⁰ cm⁻³.

The drift region 31 includes the third portion 31z in the termination region 102. The third portion 31z is in contact with the first face F1 and is in contact with the source electrode wiring layer 13. The third portion 31z functions as, for example, a current path for the SBD in the termination region 102.

The second p region 36 of p-type is provided between the drift region 31 and the first face F1. The second p region 36 is provided between the low concentration region 31a and the first face F1.

The depth of the second p region 36 is smaller than the depth of the outer peripheral p region 32 and the depth of the base region 33. The depth of the second p region 36 is smaller than the depth of the first base region 33a, for example. The depth of the second p region 36 is, for example, equal to or more than 0.5 μm and equal to or less than 1 μm.

The depth of the second p region 36 is substantially the same as the depth of the first p region 34, for example.

The second p region 36 is electrically connected to the source electrode wiring layer 13. The second p region 36 is fixed to the electric potential of the source electrode wiring layer 13. The second p region 36 is fixed to the electric potential of the source electrode 12.

The second p region 36 contains, for example, aluminum (Al) as a p-type impurity. The p-type impurity concentration in the second p region 36 is, for example, equal to or more than 5×10¹⁷ cm⁻³ and equal to or less than 1×10²⁰ cm⁻³. The p-type impurity concentration in the second p region 36 is substantially the same as the p-type impurity concentration in the first p region 34, for example.

The second p region 36 is formed by the same manufacturing process using the same mask pattern as for the first p region 34, for example.

The third p region 37 of p-type is provided between the drift region 31 and the first face F1. The third p region 37 is provided between the low concentration region 31a and the first face F1. The third p region 37 is in contact with the outer peripheral p region 32 and the second p region 36.

The depth of the third p region 37 is smaller than the depth of the outer peripheral p region 32 and the depth of the base region 33. The depth of the third p region 37 is, for example, smaller than the depth of the first base region 33a. The depth of the third p region 37 is, for example, equal to or more than 0.5 μm and equal to or less than 1 μm.

The depth of the third p region 37 is substantially the same as the depth of the first p region 34 and the depth of the second p region 36, for example.

The third p region 37 is electrically connected to the source electrode 12. The third p region 37 is fixed to the electric potential of the source electrode 12.

The third p region 37 contains, for example, aluminum (Al) as a p-type impurity. The p-type impurity concentration in the third p region 37 is, for example, equal to or more than 5×10¹⁷ cm⁻³ and equal to or less than 1×10²⁰ cm⁻³. The p-type impurity concentration in the third p region 37 is substantially the same as the p-type impurity concentration in the first p region 34 and the p-type impurity concentration in the second p region 36, for example.

The third p region 37 is formed by the same manufacturing process using the same mask pattern as for the first p region 34 and the second p region 36, for example.

The fourth p region 38 of p-type is provided between the drift region 31 and the first face F1. The fourth p region 38 is provided between the drift region 31 and the third p region 37.

The fourth p region 38 is provided, for example, between the low concentration region 31a and the first face F1. The fourth p region 38 is provided, for example, between the low concentration region 31a and the third p region 37. The fourth p region 38 is in contact with, for example, the low concentration region 31a.

The fourth p region 38 is provided on the outer periphery of the outer peripheral p region 32. The fourth p region 38 is provided on the termination region 102 side of the outer peripheral p region 32. For example, the fourth p region 38 surrounds the outer peripheral p region 32 on the first face F1.

A first width (w1 in FIG. 3) of the fourth p region 38 in the first direction is, for example, equal to or more than 0.5 times and equal to or less than 3 times the width of the base region 33 in the first direction. The first width w1 of the fourth p region 38 is equal to or more than 0.5 times and equal to or less than 3 times a second width (w2 in FIG. 3) of the first base region 33a in the first direction. The first width w1 of the fourth p region 38 is, for example, equal to or more than 0.5 μm and equal to or less than 10 μm. The first width w1 of the fourth p region 38 is substantially the same as the width of the base region 33 in the first direction, for example.

A first distance (s1 in FIG. 3) in the first direction between the fourth p region 38 and the outer peripheral p region 32 is equal to or more than 0.5 times and equal to or less than 3 times a second distance (s2 in FIG. 3) between the first base region 33a and the second base region 33b. The first distance s1 between the fourth p region 38 and the outer peripheral p region 32 is, for example, equal to or more than 0.5 μm and equal to or less than 2.0 μm.

The fourth p region 38 is provided closer to the element region 101 than the end portion of the field insulating layer 24 in the intermediate region 103 on the element region 101 side, for example.

A first depth (d1 in FIG. 3) of the fourth p region 38 is larger than the depth of the third p region 37. The first depth d1 of the fourth p region 38 is, for example, equal to or more than 1.0 μm and equal to or less than 2.0 μm. The first depth d1 of the fourth p region 38 is, for example, equal to or more than 1.5 times and equal to or less than 5 times the depth of the third p region 37.

The first depth d1 of the fourth p region 38 is, for example, equal to or more than 0.5 times and equal to or less than 2 times the depth of the base region 33. The first depth d1 of the fourth p region 38 is, for example, equal to or more than the depth of the base region 33. The first depth d1 of the fourth p region 38 is, for example, larger than the depth of the base region 33.

The first depth d1 of the fourth p region 38 is, for example, equal to or more than 0.5 times and equal to or less than 2 times the depth of the first base region 33a. The first depth d1 of the fourth p region 38 is, for example, equal to or more than the depth of the first base region 33a. The first depth d1 of the fourth p region 38 is, for example, larger than the depth of the first base region 33a.

The first depth d1 of the fourth p region 38 is, for example, equal to or more than 0.5 times and equal to or less than 2 times the second depth (d2 in FIG. 3) of the outer peripheral p region 32. The first depth d1 of the fourth p region 38 is, for example, equal to or more than the second depth d2 of the outer peripheral p region 32. The first depth d1 of the fourth p region 38 is, for example, larger than the second depth d2 of the outer peripheral p region 32.

The fourth p region 38 is electrically connected to the source electrode 12. The fourth p region 38 is fixed to the electric potential of the source electrode 12.

The fourth p region 38 contains, for example, aluminum (Al) as a p-type impurity. The p-type impurity concentration in the fourth p region 38 is, for example, equal to or more than 1×10¹⁷ cm⁻³ and equal to or less than 1×10²⁰ cm⁻³.

The p-type impurity concentration in the fourth p region 38 is, for example, equal to or more than 0.1 times and equal to or less than 2 times the p-type impurity concentration in the base region 33. The p-type impurity concentration in the fourth p region 38 is, for example, equal to or more than 0.1 times and equal to or less than 2 times the p-type impurity concentration in the first base region 33a. The p-type impurity concentration in the fourth p region 38 is substantially the same as the p-type impurity concentration in the first base region 33a, for example.

The p-type impurity concentration in the fourth p region 38 is, for example, equal to or more than 0.1 times and equal to or less than 2 times the p-type impurity concentration in the outer peripheral p region 32. The p-type impurity concentration in the fourth p region 38 is substantially the same as the p-type impurity concentration in the outer peripheral p region 32, for example.

The fourth p region 38 is formed by the same manufacturing process using the same mask pattern as for the base region 33 and the outer peripheral p region 32, for example.

A third distance (s3 in FIG. 3) in the first direction between the high concentration region 31b and the third portion 31z is larger than a third distance (s4 in FIG. 3) in the first direction between the fourth p region 38 and the third portion 31z.

The third distance s3 in the first direction between the high concentration region 31b and the third portion 31z is, for example, equal to or more than 50 μm and equal to or less than 200 μm.

The first width w1 of the fourth p region 38 is, for example, equal to or less than 1/10 of a fourth distance (s4 in FIG. 3) in the first direction between the fourth p region 38 and the third portion 31z.

The n⁺-type source region 35 is provided between the base region 33 and the first face F1. The source region 35 is provided, for example, between the second base region 33b and the first face F1. The source region 35 extends, for example, in the first direction.

The source region 35 contains, for example, phosphorus (P) or nitrogen (N) as an n-type impurity. The n-type impurity concentration in the source region 35 is higher than the n-type impurity concentration in the drift region 31.

The n-type impurity concentration in the source region 35 is, for example, equal to or more than 1×10¹⁹ cm⁻³ and equal to or less than 1×10²¹ cm⁻³. The depth of the source region 35 is smaller than the depth of the first p region 34. The depth of the source region 35 is, for example, equal to or more than 0.05 μm and equal to or less than 0.2 μm.

The source region 35 is electrically connected to the source electrode 12. The source region 35 is in contact with the silicide layer 14. The contact between the source region 35 and the source electrode 12 is, for example, an ohmic contact. The source region 35 is fixed to the electric potential of the source electrode 12.

The gate electrode 18 is provided on the first face F1 side of the silicon carbide layer 10. The gate electrode 18 extends, for example, in the second direction. A plurality of gate electrodes 18 are arranged, for example, in parallel to each other in the first direction.

The gate electrode 18 has, for example, a striped shape. The gate electrode 18 is a conductive layer. The gate electrode 18 is, for example, polycrystalline silicon containing p-type impurities or n-type impurities.

The gate electrode 18 faces the base region 33. The gate electrode 18 faces the first portion 31x.

The gate connection layer 20 is provided on the first face F1 side of the silicon carbide layer 10. The gate connection layer 20 is provided on the gate insulating layer 16 or the field insulating layer 24.

A part of the gate connection layer 20 extends, for example, in a direction perpendicular to the gate electrode 18. The gate connection layer 20 has a function of electrically connecting the gate electrode 18 and the gate electrode pad 22 to each other.

The gate connection layer 20 is formed of, for example, the same material as the gate electrode 18.

The gate pad layer 21 is provided on the first face F1 side of the silicon carbide layer 10. The gate pad layer 21 is provided on the field insulating layer 24.

The gate pad layer 21 is physically and electrically connected to the gate connection layer 20. The gate pad layer 21 has a function of electrically connecting the gate electrode 18 and the gate electrode pad 22 to each other.

The gate pad layer 21 is formed of, for example, the same material as the gate electrode 18 and the gate connection layer 20.

The gate insulating layer 16 is provided between the gate electrode 18 and the base region 33. The gate insulating layer 16 is provided between the gate electrode 18 and the first portion 31x. The gate insulating layer 16 is provided between the gate electrode 18 and the source region 35.

The gate insulating layer 16 is, for example, a silicon oxide. For example, a high-k insulating material (insulating material with a high dielectric constant) can be applied to the gate insulating layer 16.

The field insulating layer 24 is provided on the silicon carbide layer 10 in the intermediate region 103.

The field insulating layer 24 is, for example, a silicon oxide.

The interlayer insulating layer 26 is provided on the gate electrode 18 and the silicon carbide layer 10. The interlayer insulating layer 26 is, for example, a silicon oxide.

The source electrode 12 is provided on the first face F1 side of the silicon carbide layer 10 in the element region 101. The source electrode 12 is provided on the interlayer insulating layer 26.

The source electrode 12 is in contact with the silicon carbide layer 10 in the element region 101. The source electrode 12 is in contact with the silicide layer 14. The source electrode 12 is in contact with the second portion 31y.

The silicide layer 14 contains a silicide. The silicide layer 14 is, for example, a nickel silicide or a titanium silicide.

The contact between the source electrode 12 and the source region 35 becomes an ohmic contact by interposing the silicide layer 14 therebetween. The contact between the source electrode 12 and the base region 33 becomes an ohmic contact by interposing the silicide layer 14 therebetween. The contact between the source electrode 12 and the first p region 34 becomes s an ohmic contact by interposing the silicide layer 14 therebetween.

The source electrode 12 contains metal. The source electrode 12 has, for example, a stacked structure of titanium (Ti) and aluminum (Al).

The source electrode 12 is in contact with the second portion 31y. The contact between the source electrode 12 and the second portion 31y is a Schottky contact.

The source electrode wiring layer 13 is provided on the first face F1 side of the silicon carbide layer 10 in the termination region 102. The source electrode wiring layer 13 is provided on the interlayer insulating layer 26.

The source electrode wiring layer 13 is physically and electrically connected to the source electrode 12. The source electrode wiring layer 13 surrounds the source electrode 12, for example.

The source electrode wiring layer 13 is in contact with the silicon carbide layer 10 in the termination region 102. The source electrode wiring layer 13 is in contact with the silicide layer 14. The source electrode wiring layer 13 is in contact with the third portion 31z.

The contact between the source electrode wiring layer 13 and the second p region 36 becomes an ohmic contact by interposing the silicide layer 14 therebetween.

The source electrode wiring layer 13 contains metal. The source electrode 12 has, for example, a stacked structure of titanium (Ti) and aluminum (Al).

The source electrode wiring layer 13 is in contact with the third portion 31z. The contact between the source electrode wiring layer 13 and the third portion 31z is a Schottky contact.

The gate electrode pad 22 is provided on the first face F1 side of the silicon carbide layer 10 in the intermediate region 103. The gate electrode pad 22 is provided on the interlayer insulating layer 26.

The gate electrode pad 22 contains metal. The gate electrode pad 22 has, for example, a stacked structure of titanium (Ti) and aluminum (Al). The gate electrode pad 22 is formed of, for example, the same material as the source electrode 12 and the source electrode wiring layer 13.

The gate electrode wiring layer 23 is provided on the first face F1 side of the silicon carbide layer 10 in the intermediate region 103. The gate electrode wiring layer 23 is provided on the interlayer insulating layer 26.

The gate electrode wiring layer 23 is physically and electrically connected to the gate electrode pad 22. The gate electrode wiring layer 23 is physically and electrically connected to the gate connection layer 20.

The gate electrode wiring layer 23 contains metal. The source electrode 12 has, for example, a stacked structure of titanium (Ti) and aluminum (Al). The gate electrode wiring layer 23 is formed of, for example, the same material as the source electrode 12, the source electrode wiring layer 13, and the gate electrode pad 22.

The drain electrode 15 is provided on the back surface of the silicon carbide layer 10. The drain electrode 15 is in contact with the drain region 30.

The drain electrode 15 is, for example, a metal or a metal semiconductor compound. The drain electrode 15 contains at least one material selected from a group consisting of nickel silicide, titanium (Ti), nickel (Ni), silver (Ag), and gold (Au), for example.

In the element region 101, the gate electrode 18, the gate insulating layer 16, the base region 33, the source region 35, the first portion 31x of the drift region 31, the drain region 30, the source electrode 12, and the drain electrode 15 form a MOSFET. When the MOSFET 100 is in an on state, a current flows from the drain electrode 15 to the source electrode 12 due to the MOSFET in the element region 101.

In the element region 101, the source electrode 12, the second portion 31y of the drift region 31, the drain region 30, and the drain electrode 15 form an SBD. When a voltage positive with respect to the drain electrode 15 is applied to the source electrode 12 while the MOSFET 100 is in an off state, a current flows from the source electrode 12 to the drain electrode 15 due to the SBD in the element region 101.

In the termination region 102, the source electrode wiring layer 13, the third portion 31z of the drift region 31, the drain region 30, and the drain electrode 15 form an SBD. When a voltage positive with respect to the drain electrode 15 is applied to the source electrode 12 while the MOSFET 100 is in an off state, a current flows from the source electrode wiring layer 13 to the drain electrode 15 due to the SBD in the termination region 102.

Next, the function and effect of the MOSFET 100 according to the first embodiment will be described.

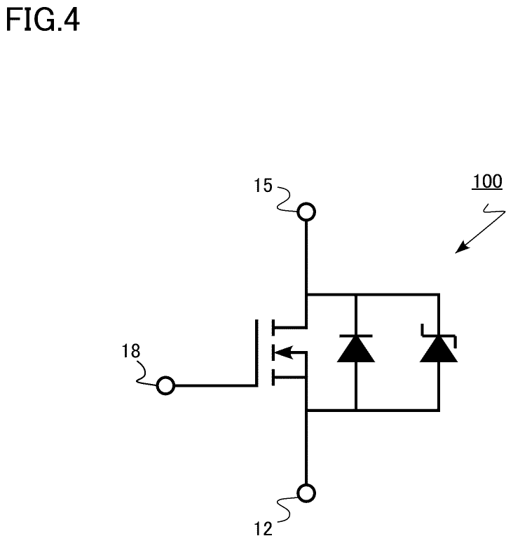

FIG. 4 is an equivalent circuit diagram of the semiconductor device according to the first embodiment. In the MOSFET 100, between the source electrode 12 and the drain electrode 15 in the element region 101, a pn junction diode and an SBD are connected as built-in diodes in parallel with a transistor. The base region 33 is on the anode side of the pn junction diode, and the drift region 31 is on the cathode side of the pn junction diode. In addition, the source electrode 12 serves as the anode of the SBD, and the drain electrode 15 serves as the cathode of the SBD.

For example, a case where the MOSFET 100 is used as a switching element connected to an inductive load is considered. When the MOSFET 100 is turned off, a voltage that is positive with respect to the drain electrode 15 may be applied to the source electrode 12 due to an induced current caused by an inductive load. In this case, a forward current flows through the built-in diode. This state is also referred to as a reverse conduction state.

If the MOSFET does not include an SBD, a forward current flows through the pn junction diode. The pn junction diode operates in a bipolar manner. When a reflux current is made to flow by using a pn junction diode that operates in a bipolar manner, a stacking fault grows in a silicon carbide layer due to the recombination energy of the carriers. When the stacking fault grows in the silicon carbide layer, there arises a problem that the on-resistance of the MOSFET increases. Increasing the on-resistance of the MOSFET leads to a reduction in the reliability of the MOSFET.

The MOSFET 100 includes an SBD. A forward voltage (Vf) at which a forward current starts to flow through the SBD is lower than a forward voltage (Vf) of the pn junction diode. Therefore, a forward current flows through the SBD prior to the pn junction diode.

The forward voltage (Vf) of the SBD is, for example, equal to or more than 1.0 V and less than 2.0 V. The forward voltage (Vf) of the pn junction diode is, for example, equal to or more than 2.0 V and equal to or less than 3.0 V.

The SBD operates in a unipolar manner. Therefore, even if a forward current flows, no stacking fault grows in the silicon carbide layer 10 due to the recombination energy of the carriers. Therefore, the increase in the on-resistance of the MOSFET 100 is suppressed. As a result, the reliability of the MOSFET 100 is improved.

In addition, since the forward current flows through the SBD, the voltage on the N side of the pn junction diode rises, and the voltage applied to the pn junction in the vicinity of the SBD effectively drops. Therefore, by providing the SBD, the forward voltage (Vf) of the pn junction diode in the vicinity of the SBD can be effectively increased. Therefore, the flow of the forward current to the pn junction diode is suppressed. In other words, the operation start voltage of the pn junction diode can be increased. As a result, the reliability of the MOSFET 100 is improved.

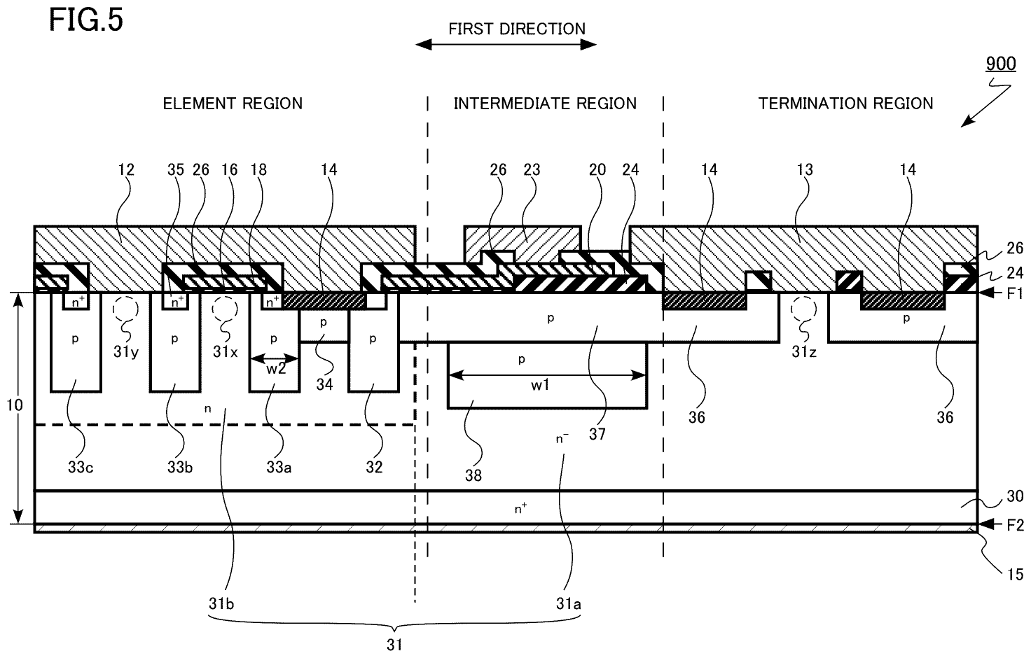

FIG. 5 is a schematic cross-sectional view of a semiconductor device according to a comparative example. The semiconductor device according to the comparative example is a MOSFET 900. FIG. 5 is a diagram corresponding to FIG. 3 in the first embodiment.

The MOSFET 900 according to the comparative example is different from the MOSFET 100 according to the first embodiment in that the first width (w1 in FIG. 5) of the fourth p region 38, which is provided in the intermediate region 103, in the first direction is larger than three times the second width (w2 in FIG. 5) of the first base region 33a in the first direction.

In the MOSFET 900 according to the comparative example, a third p region 37 of p-type and a fourth p region 38 of p-type deeper than the third p region 37 are provided outside the n-type high concentration region 31b provided in the element region 101. With this configuration, when the MOSFET 900 is in an off state, the strength of the electric field applied to the termination portion of the pn junction in the element region 101 is reduced. Therefore, the dielectric breakdown voltage of the MOSFET 900 is increased.

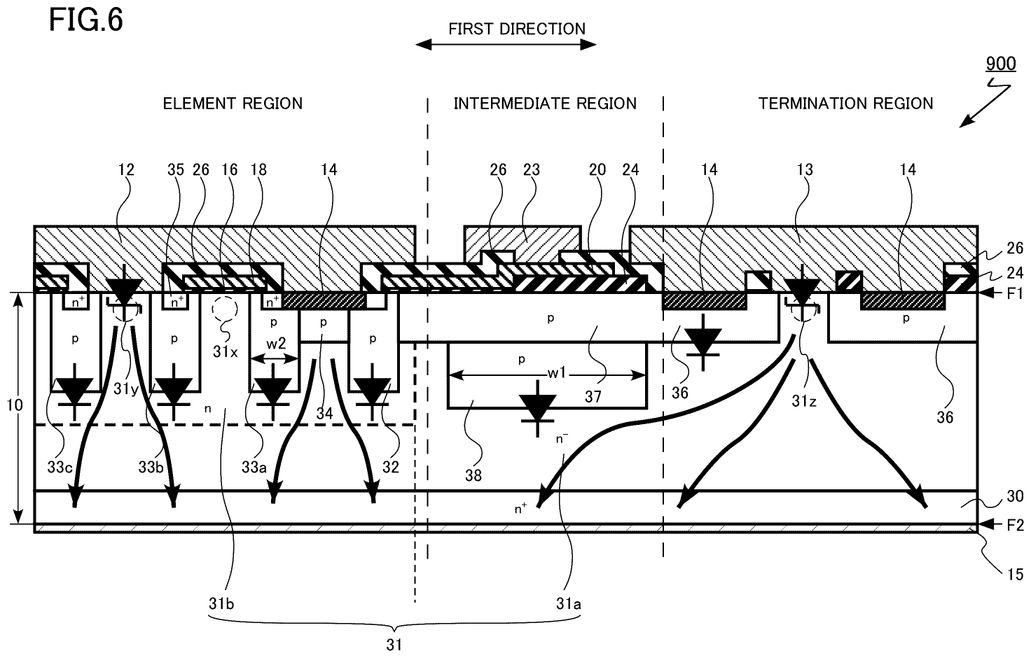

FIG. 6 is an explanatory diagram of the function and effect of the semiconductor device according to the first embodiment. FIG. 6 is a schematic cross-sectional view of the semiconductor device according to the comparative example. FIG. 6 is a diagram corresponding to FIG. 5.

FIG. 6 shows pn junction diodes and SBDs built in the MOSFET 900 using circuit symbols. In addition, FIG. 6 shows by arrows a current that flows through the MOSFET 900 when a voltage that is positive with respect to the drain electrode 15 is applied to the source electrode 12 of the MOSFET 900.

As shown in FIG. 6, in the element region 101, a forward current flows through the SBD including the source electrode 12 and the second portion 31y of the drift region 31. The forward current passes between the base regions 33 and flows around the bottom portion of the base region 33. Due to the forward current flowing around the bottom portion of the base region 33, a voltage on the N side of the pn junction diode formed by the base region 33 and the drift region 31 rises, and a voltage applied to the pn junction in the vicinity of the SBD effectively drops. Therefore, the forward voltage (Vf) of the pn junction diode in the element region 101 can be effectively increased. As a result, the flow of the forward current to the pn junction diode in the element region 101 is suppressed.

As shown in FIG. 6, in the termination region 102, a forward current flows through the SBD including the source electrode wiring layer 13 and the third portion 31z of the drift region 31. The forward current passes between the second p regions 36 and flows around the bottom portions of the second p region 36, the third p region 37, and the fourth p region 38. However, since there is a distance from the SBD in the termination region 102 to the fourth p region 38 close to the element region 101, the flow of current around the bottom portion of the fourth p region 38 close to the element region 101 is suppressed.

For this reason, in a portion close to the element region 101, an increase in the voltage on the N side of the pn junction diode formed by the fourth p region 38 and the drift region 31 is unlikely to occur. That is, a decrease in voltage applied to the pn junction due to the forward current is suppressed. Therefore, the pn junction diode in the element region 101 operates, making it easier for a bipolar current to flow through the drift region 31. As a result, there is a concern that the reliability of the MOSFET 900 may be reduced due to an increase in the on-resistance.

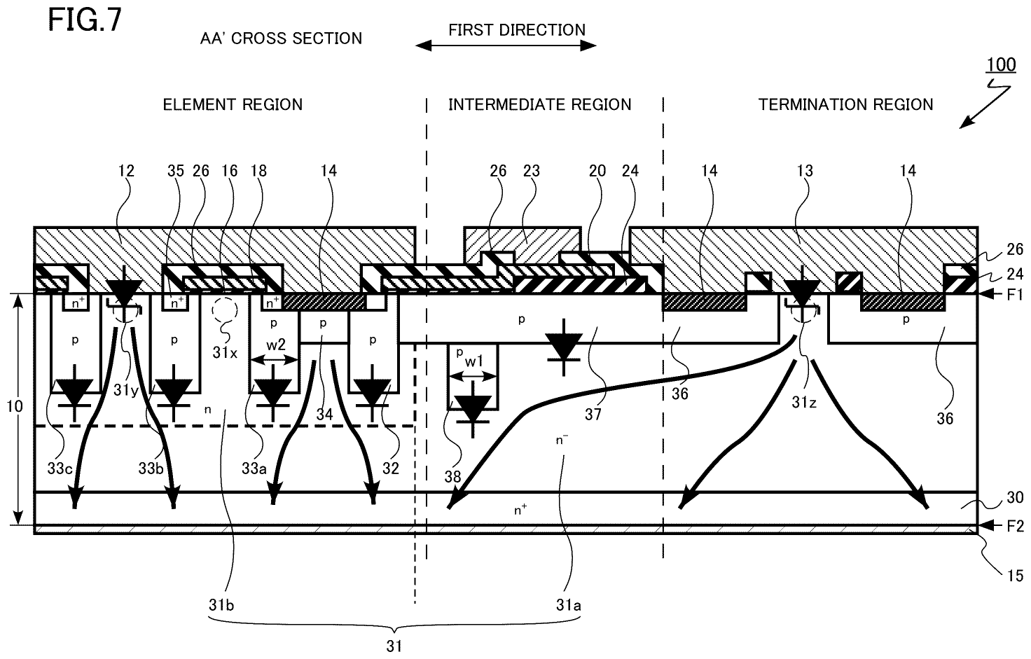

FIG. 7 is an explanatory diagram of the function and effect of the semiconductor device according to the first embodiment. FIG. 7 is a schematic cross-sectional view of the semiconductor device according to the first embodiment. FIG. 7 is a diagram corresponding to FIG. 3.

FIG. 7 shows pn junction diodes and SBDs built in the MOSFET 100 using circuit symbols. In addition, FIG. 7 shows by arrows a current that flows through the MOSFET 100 when a voltage that is positive with respect to the drain electrode 15 is applied to the source electrode 12 of the MOSFET 100.

As shown in FIG. 7, in the element region 101, a forward current flows through the SBD including the source electrode 12 and the second portion 31y of the drift region 31, similarly to the MOSFET 900 according to the comparative example shown in FIG. 6. As a result, the flow of the forward current to the pn junction diode in the element region 101 is suppressed, similarly to the MOSFET 900 according to the comparative example.

As shown in FIG. 7, in the MOSFET 100 according to the first embodiment, the first width (w1 in FIG. 7) of the fourth p region 38, which is provided in the intermediate region 103, in the first direction is equal to or less than three times the second width (w2 in FIG. 7) of the first base region 33a in the first direction. The first width w1 of the fourth p region 38 is reduced as compared with the MOSFET 900 according to the comparative example.

Since the first width w1 of the fourth p region 38 is reduced, the proportion of the deep p-type region in the intermediate region 103 is reduced. Therefore, the current flowing from the SBD in the termination region 102 is promoted to flow around the bottom portion of the fourth p region 38 close to the element region 101.

For this reason, in a portion close to the element region 101, an increase in the voltage on the N side of the pn junction diode formed by the fourth p region 38 and the drift region 31 is likely to occur. This promotes a reduction in the voltage applied to the pn junction due to the forward current. Therefore, the pn junction diode in the element region 101 becomes less likely to operate, making it difficult for a bipolar current to flow through the drift region 31. As a result, the generation of a stacking fault is suppressed to improve the reliability of the MOSFET 100.

From the viewpoint of promoting the flow of current around the bottom portion of the fourth p region 38 to improve the reliability of the MOSFET 100, the first width w1 of the fourth p region 38 is preferably equal to or less than twice, more preferably equal to or less than 1.5times, and even more preferably equal to or less than 1 time the second width w2 of the first base region 33a in the first direction.

From the viewpoint of reducing the strength of the electric field applied to the termination portion of the pn junction in the element region 101 to increase the dielectric breakdown voltage of the MOSFET 100, the first width w1 of the fourth p region 38 is preferably equal to or more than 0.75 times, more preferably equal to or more than 1 time the width w2 of the first base region 33a in the first direction.

From the viewpoint of promoting the flow of current around the bottom portion of the fourth p region 38 to improve the reliability of the MOSFET 100, the first width w1 of the fourth p region 38 is preferably equal to or less than 10 μm, more preferably equal to or less than 5 μm, even more preferably equal to or less than 3 μm, and most preferably equal to or less than 1.5 μm.

From the viewpoint of reducing the strength of the electric field applied to the termination portion of the pn junction in the element region 101 to increase the dielectric breakdown voltage of the MOSFET 100, the first width w1 of the fourth p region 38 is preferably equal to or more than 0.5 μm, and more preferably equal to or more than 1.0 μm.

From the viewpoint of reducing the strength of the electric field applied to the termination portion of the pn junction in the element region 101 to increase the dielectric breakdown voltage of the MOSFET 100, the p-type impurity concentration in the fourth p region 38 is preferably equal to or more than 0.1 times and equal to or less than 2 times the p-type impurity concentration in the first base region 33a.

From the viewpoint of reducing the strength of the electric field applied to the termination portion of the pn junction in the element region 101 to increase the dielectric breakdown voltage of the MOSFET 100, the p-type impurity concentration in the fourth p region 38 is preferably equal to or more than 0.1 times and equal to or less than 2 times the p-type impurity concentration in the outer peripheral p region 32.

From the viewpoint of reducing the strength of the electric field applied to the termination portion of the pn junction in the element region 101 to increase the dielectric breakdown voltage of the MOSFET 100, it is preferable that the depth of the fourth p region 38 is larger than the depths of the base region 33 and the outer peripheral p region 32.

From the viewpoint of reducing the strength of the electric field applied to the termination portion of the pn junction in the element region 101 to increase the dielectric breakdown voltage of the MOSFET 100, the first distance s1 in the first direction between the fourth p region 38 and the outer peripheral p region 32 is preferably equal to or more than 0.75 times and equal to or less than 2 times the second distance (s2 in FIG. 3) between the first base region 33a and the second base region 33b.

From the viewpoint of reducing the strength of the electric field applied to the termination portion of the pn junction in the element region 101 to increase the dielectric breakdown voltage of the MOSFET 100, it is preferable that the third distance (s3 in FIG. 3) in the first direction between the high concentration region 31b and the third portion 31z is larger than the fourth distance (s4 in FIG. 3) in the first direction between the fourth p region 38 and the third portion 31z.

From the viewpoint of promoting the flow of current around the bottom portion of the fourth p region 38 to improve the reliability of the MOSFET 100, the first width w1 of the fourth p region 38 in the first direction is preferably equal to or less than 1/10, more preferably equal to or less than 1/20, and even more preferably equal to or less than 1/50 of the fourth distance (s4 in FIG. 3) in the first direction between the fourth p region 38 and the third portion 31z.

As described above, according to the first embodiment, a MOSFET is realized in which the flow of a forward current to a pn junction diode is suppressed to improve the reliability.

### (Second Embodiment)

A semiconductor device according to a second embodiment is different from the semiconductor device according to the first embodiment in that the semiconductor device according to the second embodiment further includes an eleventh silicon carbide region of a first conductive type provided between the tenth silicon carbide region and the first face. Hereinafter, the description of a part of the content overlapping the first embodiment may be omitted.

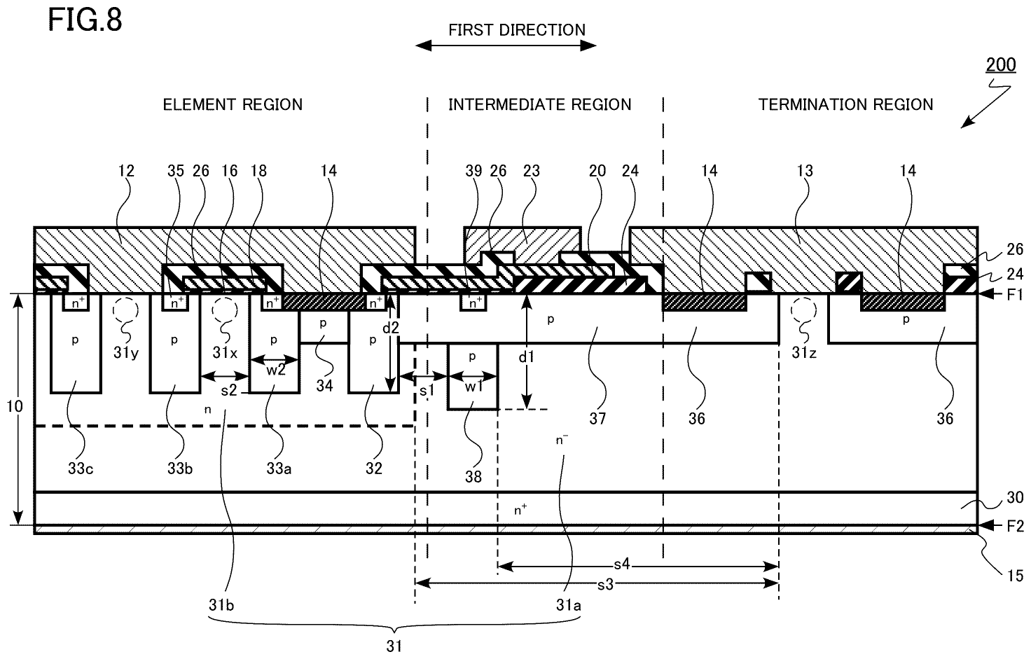

FIG. 8 is a schematic cross-sectional view of the semiconductor device according to the second embodiment. FIG. 8 is a diagram corresponding to FIG. 3 in the first embodiment.

The semiconductor device according to the second embodiment is a planar gate vertical MOSFET 200 using silicon carbide. The MOSFET 200 is, for example, a DIMOSFET in which a base region and a source region are formed by ion implantation. In addition, the semiconductor device according to the second embodiment includes an SBD as a built-in diode.

Hereinafter, a case where the first conductive type is n-type and the second conductive type is p-type will be described as an example. The MOSFET 200 is a vertical n-channel MOSFET having electrons as carriers.

The MOSFET 200 includes a silicon carbide layer 10, a source electrode 12 (first electrode), a source electrode wiring layer 13 (wiring layer), a silicide layer 14, a drain electrode 15 (second electrode), a gate insulating layer 16, a gate electrode 18, a gate connection layer 20, a gate pad layer 21, a gate electrode pad 22, a gate electrode wiring layer 23, a field insulating layer 24, and an interlayer insulating layer 26.

The silicon carbide layer 10 includes an n⁺-type drain region 30, an n-type drift region 31 (first silicon carbide region), a p-type outer peripheral p region 32 (third silicon carbide region), a p-type first base region 33a (fourth silicon carbide region), a p-type second base region 33b (fifth silicon carbide region), a p-type third base region 33c (second silicon carbide region), a p-type first p region 34 (sixth silicon carbide region), an n⁺-type source region 35 (seventh silicon carbide region), a p-type second p region 36 (eighth silicon carbide region), a p-type third p region 37 (ninth silicon carbide region), a p-type fourth p region 38 (tenth silicon carbide region), and an n⁺-type floating region 39 (eleventh silicon carbide region). The n-type drift region 31 (first silicon carbide region) has an n⁻-type low concentration region 31a (first region) and an n-type high concentration region 31b (second region). The n-type drift region 31 has a first portion 31x, a second portion 31y, and a third portion 31z.

The n⁺-type floating region 39 is provided between the fourth p region 38 and the first face F1. The floating region 39 is provided directly above the fourth p region 38. The floating region 39 is in contact with the first face F1. The floating region 39 is provided in the third p region 37.

The floating region 39 is electrically floating. The floating region 39 is not electrically connected to any of the source electrode 12, the drain electrode 15, and the gate electrode 18.

The fourth p region 38 and the floating region 39 are formed by the same manufacturing process using the same mask pattern as for the base region 33 and the source region 35, for example. By forming the fourth p region 38 and the floating region 39 in the same manufacturing process using the same mask pattern as for the base region 33 and the source region 35, it is possible to shorten the manufacturing process of the MOSFET 200 and reduce the manufacturing cost, for example.

As described above, according to the second embodiment, as in the first embodiment, the flow of a forward current to the pn junction diode is suppressed to realize a MOSFET with improved reliability.

In the first or second embodiment, the case of 4H-SiC has been described as an example of the crystal structure of SiC. However, embodiments can also be applied to devices using SiC having other crystal structures, such as 6H-SiC and 3C-SiC. In addition, a face other than the (0001) face can also be applied as the surface of the silicon carbide layer 10.

In the first or second embodiment, the case where the first conductive type is n-type and the second conductive type is p-type has been described as an example. However, the first conductive type can be p-type and the second conductive type can be n-type.

In the first or second embodiment, aluminum (Al) is exemplified as a p-type impurity, but boron (B) can also be used. In addition, although nitrogen (N) and phosphorus (P) are exemplified as n-type impurities, arsenic (As), antimony (Sb), and the like can also be applied.

In the first or second embodiment, the case where the gate electrode 18 in the element region 101 has a striped shape has been described as an example. However, for example, the gate electrode 18 may have a mesh-shaped structure.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
an element region;
a termination region surrounding the element region; and
an intermediate region provided between the element region and the termination region and surrounding the element region,
wherein the element region includes:
a first electrode;
a second electrode;
a gate electrode;
a silicon carbide layer provided between the first electrode and the second electrode, having a first face on the first electrode side and a second face on the second electrode side, and including:
a first silicon carbide region of a first conductive type having a first region, a second region provided between the first region and the first face and having a higher first conductive type impurity concentration than the first region, a first portion in contact with the first face and facing the gate electrode, and a second portion in contact with the first face and in contact with the first electrode;
a second silicon carbide region of a second conductive type provided between the second region and the first face and electrically connected to the first electrode;
a third silicon carbide region of the second conductive type provided between the second region and the first face, provided on the intermediate region side of the second silicon carbide region, and electrically connected to the first electrode;
a fourth silicon carbide region of the second conductive type provided between the second region and the first face, provided between the second silicon carbide region and the third silicon carbide region, facing the gate electrode, and electrically connected to the first electrode;
a fifth silicon carbide region of the second conductive type provided between the second region and the first face, provided between the second silicon carbide region and the fourth silicon carbide region, facing the gate electrode, and electrically connected to the first electrode;
a sixth silicon carbide region of the second conductive type provided between the second region and the first face, provided between the third silicon carbide region and the fourth silicon carbide region, and having a depth smaller than a depth of the third silicon carbide region and a depth of the fourth silicon carbide region; and
a seventh silicon carbide region of the first conductive type provided between the fifth silicon carbide region and the first face and electrically connected to the first electrode; and
a gate insulating layer provided between the gate electrode and the fifth silicon carbide region and between the gate electrode and the first portion,
the termination region includes:
a wiring layer electrically connected to the first electrode;
the second electrode; and
the silicon carbide layer including the first silicon carbide region having a third portion in contact with the first face and in contact with the wiring layer and an eighth silicon carbide region of the second conductive type provided between the first silicon carbide region and the first face, electrically connected to the wiring layer, and having a smaller depth than the third silicon carbide region, and
the intermediate region includes:
the second electrode; and
the silicon carbide layer including:
the first silicon carbide region;
a ninth silicon carbide region of the second conductive type provided between the first silicon carbide region and the first face, electrically connected to the first electrode, in contact with the third silicon carbide region and the eighth silicon carbide region, and having a smaller depth than the third silicon carbide region; and
a tenth silicon carbide region of the second conductive type provided between the first silicon carbide region and the ninth silicon carbide region, a first width of the tenth silicon carbide region in a first direction parallel to the first face being equal to or more than 0.5 times and equal to or less than 3 times a second width of the fourth silicon carbide region in the first direction, and a first distance in the first direction between the tenth silicon carbide region and the third silicon carbide region being equal to or more than 0.5 times and equal to or less than 3 times a second distance in the first direction between the fourth silicon carbide region and the fifth silicon carbide region.

2. The semiconductor device according to claim 1,
wherein the first width is equal to or less than twice the second width.

3. The semiconductor device according to claim 1,
wherein the first width is equal to or more than 0.5 μm and equal to or less than 10 μm.

4. The semiconductor device according to claim 1,
wherein a second conductive type impurity concentration in the tenth silicon carbide region is equal to or more than 0.1 times and equal to or less than 2 times a second conductive type impurity concentration in the third silicon carbide region.

5. The semiconductor device according to claim 1,
wherein a first depth of the tenth silicon carbide region is larger than a second depth of the third silicon carbide region.

6. The semiconductor device according to claim 1,
wherein the tenth silicon carbide region is in contact with the first region.

7. The semiconductor device according to claim 1,
wherein a third distance in the first direction between the second region and the third portion is larger than a fourth distance in the first direction between the tenth silicon carbide region and the third portion.

8. The semiconductor device according to claim 1,
wherein the first width is equal to or less than 1/10 of a fourth distance in the first direction between the tenth silicon carbide region and the third portion.

9. The semiconductor device according to claim 1, further comprising:
an eleventh silicon carbide region of the first conductive type provided between the tenth silicon carbide region and the first face.

10. The semiconductor device according to claim 9,
wherein the eleventh silicon carbide region is electrically floating.

11. The semiconductor device according to claim 1,
wherein the gate electrode extends in a second direction parallel to the first face and perpendicular to the first direction.

12. The semiconductor device according to claim 1,
wherein the second silicon carbide region, the fourth silicon carbide region, and the fifth silicon carbide region extend in a second direction parallel to the first face and perpendicular to the first direction.

13. The semiconductor device according to claim 1,
wherein the ninth silicon carbide region is in contact with the first face.

14. The semiconductor device according to claim 1,
wherein the ninth silicon carbide region is in contact with the tenth silicon carbide region.

15. The semiconductor device according to claim 1,
wherein a depth of the third silicon carbide region is substantially equal to a depth of the fourth silicon carbide region.

16. The semiconductor device according to claim 1,
wherein the contact between the first electrode and the second portion is a Schottky contact.

17. The semiconductor device according to claim 1,
wherein the contact between the wiring layer and the third portion is a Schottky contact.

18. The semiconductor device according to claim 1, further comprising:
a silicide layer disposed between the first electrode and the sixth silicon carbide region.

19. The semiconductor device according to claim 1, further comprising:
a silicide layer provided between the wiring layer and the eighth silicon carbide region.

20. The semiconductor device according to claim 1,
wherein, on the first face, the third silicon carbide region surrounds the fourth silicon carbide region.
